(19) United States
(12) Patent Application Publication
(10) Pub. No.: US 2024/0332227 A1
(43) Pub. Date: Oct. 3, 2024

(54) SEMICONDUCTOR ELEMENT WITH BONDING LAYER HAVING LOW-K DIELECTRIC MATERIAL

(71) Applicant: ADEIA SEMICONDUCTOR BONDING TECHNOLOGIES INC, San Jose, CA (US)

(72) Inventors: Cyprian Emeka Uzoh, San Jose, CA (US); Oliver Zhao, Sunnyvale, CA (US)

(21) Appl. No.: 18/194,544

(22) Filed: Mar. 31, 2023

(51) Int. Cl. H01L 23/00

(52) U.S. Cl. CPC H01L 24/05; H01L 24/03; H01L 24/08; H01L 2224/03614; H01L 2224/0382; H01L 2224/03826; H01L 2224/03827; H01L 2224/03845; H01L 2224/05026; H01L 2224/05073; H01L 2224/05157; H01L 2224/05166; H01L 2224/0517; H01L 2224/05176; H01L 2224/05181; H01L 2224/05184; H01L 2224/05186; H01L 2224/05562; H01L 2224/05567; H01L 2224/05573; H01L 2224/05624; H01L 2224/05638; H01L 2224/05647; H01L 2224/05655; H01L 2224/05684; H01L 2224/08145; H01L 2924/01014; H01L 2924/04941; H01L 2924/04953; H01L 2924/0496; H01L 2924/0543

(57) ABSTRACT

A semiconductor element having an interconnect bonding layer with a contact pad and a plasma damage-free low-k dielectric material is disclosed. The contact pad connects an underlying conductive feature through an intervening via. A thin dielectric layer is disposed on and covering the entire sidewalls of the contact pad, the intervening via and the underlying conductive feature, and making an approximately right angle turn to extend along an interface between the low-k dielectric material and a first dielectric layer that at least partially bury the underlying contact feature.

### BACKGROUND

### Field

The field relates to microelectronics with a bonding layer comprising a low-k dielectric material.

### Description of the Related Art

The semiconductor industry has experienced tremendous growth over the past several decades as integrated circuit (IC) engineers have developed chips with ever smaller technology nodes, which create ever smaller transistors on a chip or integrated device die. However, as integration increases, parasitic capacitance or resistance capacitance (RC), which is produced by the conductors and dielectric materials in interconnects, becomes significant enough to cause interconnect-induced delays. The negative effect of RC becomes more profound when the technology nodes get smaller and integration gets higher. With the decreasing of device dimensions, both the resistance and the interline capacitance increase due to the decrease of the conductor cross section, the increase of the wire length, and the reduction of interconnect spacing. Hence, the RC delay is significantly increased with the advance of the technology node. In order to bring down RC delay, new materials have been introduced to the back-end-of-line (BEOL) interconnects. For example, aluminum (Al) has been replaced by copper (Cu) as a conductor because Cu can provide lower resistivity. In the case of the interconnecting nonconductor, dielectric materials with low dielectric constant k have been adopted. Additionally, the changing of conductor to Cu and nonconductive materials to low-k dielectric has pushed fabrication methods to advance. Traditional metal etching approach has been replaced by a damascene process.

### BRIEF DESCRIPTION OF THE DRAWINGS

Specific implementations will now be described with reference to the following drawings, which are provided by way of example, and not limitation.

FIG. 1 is a schematic cross-sectional view of a semiconductor element comprising a conductive contact pad embedded in a non-low-k dielectric bonding layer connecting to a underlaying conductive feature through an intervening via.

FIG. 2 is a schematic cross-sectional view of an embodiment of a semiconductor element comprising a plurality of conductive contact pads embedded in a low-k dielectric bonding layer, each of the contact features connecting to an underlying conductive feature through an intervening via.

FIG. 2A is a detail schematic cross-sectional view showing one of the conductive features in FIG. 2, including a conductive pad embedded in a low-k dielectric bonding layer and connecting to an underlying conductive feature through an intervening via.

FIGS. 3-6 are schematic cross-sectional views illustrating example process steps to fabricate the semiconductor element of FIG. 2.

FIG. 7 is a schematic cross-sectional view of a semiconductor element that has the same structure as the semiconductor element of FIG. 2, except there exist voids in the low-k dielectric bonding layer.

FIGS. 8-11 are schematic cross-sectional views illustrating example process steps to fabricate another embodiment of a semiconductor element shown in FIG. 11.

FIG. 12 is a schematic cross-sectional view of a semiconductor element that has the same structure as the semiconductor element of FIG. 11, except there exist voids in the low-k dielectric bonding layer.

FIG. 13 is a schematic cross-sectional view of another embodiment of a semiconductor element comprising a plurality of conductive contact pads embedded in a low-k dielectric bonding layer, each contact pad connecting to an underlying conductive feature through an intervening via, each contact pad and the connected via formed uniformly through a dual damascene process.

FIG. 14 is a schematic cross-sectional view of a semiconductor element that has the same structure as the semiconductor element of FIG. 2, except the bonding structure comprises a thin dielectric top layer forming partially the top bonding surface.

FIG. 15 is a schematic cross-sectional view of a bonded structure comprising two semiconductor elements of FIG. 2 directly bonded together.

FIG. 16 is a schematic cross-sectional view of a bonded structure comprising a semiconductor element of FIG. 2 having a low-k dielectric material in the bonding layer directly bonded to semiconductor element having a non-low-k dielectric material in the bonding layer.

FIG. 17 is a schematic cross-sectional view of a bonded structure comprising a plurality of semiconductor elements of FIG. 2 directly bonded to a wafer having a plurality of semiconductor modules having a bonding layer with a low-k dielectric material.

FIG. 18 is a schematic cross-sectional view of the bonded structure of FIG. 17 coated with a protective layer and ready to be singulated.

FIG. 19 is a schematic cross-sectional view of a bonded structure comprising a plurality of semiconductor elements of FIG. 18 after singulation.

FIG. 20 is a schematic cross-sectional view of a bonded structure encapsulated with an ALD coated barrier layer.

FIG. 21 is a schematic cross-sectional view of another bonded structure encapsulated with an ALD coated barrier layer.

FIG. 22 is a schematic cross-sectional view of an embodiment of a semiconductor element comprising a low-k dielectric layer and thin conductive layers in the low-k dielectric layer forming Faraday cages around conductive features.

FIG. 23 is a schematic cross-sectional view of another embodiment of a semiconductor element comprising a low-k dielectric layer and thin conductive layers in the low-k dielectric layer forming Faraday cages around conductive features.

FIG. 24 is a schematic cross-sectional view of two microelectronic elements configured to be bonded together.

FIG. 25 is a schematic cross-sectional view of bonded structure comprising the two microelectronic elements in FIG. 14 bonded together.

### DETAILED DESCRIPTION

In damascene processes, plasma technology is widely used because it can provide an isotropic or anisotropic etch process at a fast rate. These changes cause the low-k dielectric material sidewalls to come directly in contact with the plasma, such as in dielectric etching, photo stripping, barrier metal deposition, and surface treatment. Such plasma damage can increase the dielectric constant, moisture absorption, or degrade the desirable properties of the plasma exposed dielectric layer. These plasma related defects are an impediment to successful integration of low-k dielectric materials into semiconductor fabrication processing.

Plasma induced damages to a low-k dielectric material can happen in different ways. For example, under physical and chemical reactions with the plasma, the surface of the low-k dielectric material can be modified, e.g., increase in dielectric constant of exposed dielectric regions, roughened sidewalls of trenches, vias, or undercut, etc. The modification depth is related to the ion energy, diffusion of active radicals (O, H, F, etc.), and porosity and constituents in the low-k material. This type of plasma damage in the low-k dielectric material can be characterized by an increase of the dielectric constant k, changes in bonding configuration, formation of a carbon-depleted layer, film shrinkage, and surface densification.

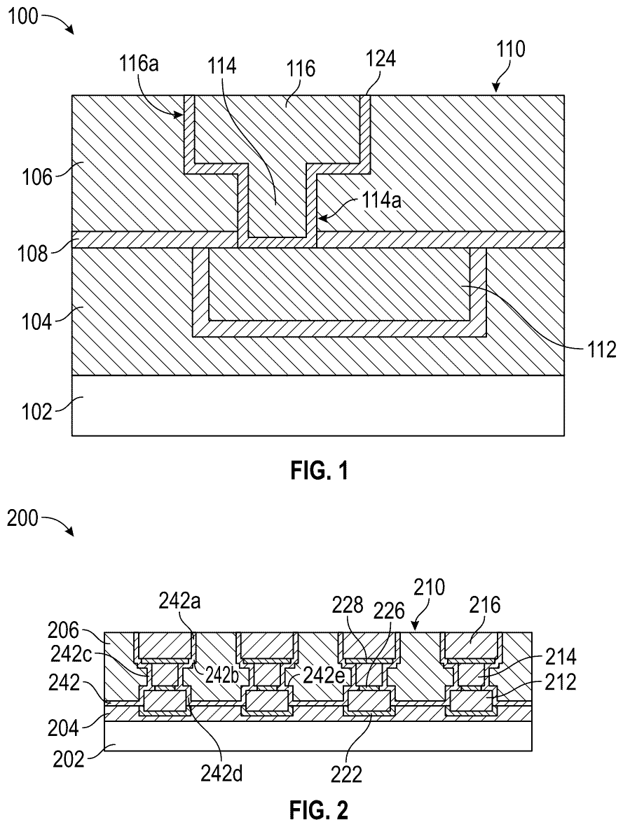

FIG. 1 shows a schematic cross-sectional view of a portion of a semiconductor element 100. The semiconductor element 100 can comprise a substrate 102. such as a semiconductor substrate (e.g., silicon). The substrate 102 can comprise active circuitry and/or other devices formed therein. A first dielectric material layer 104 can be provided over the substrate 102, and a second nonconductive or dielectric material 106 can be provided over the first dielectric material layer 104. In various embodiments, an etch stop layer 108 can be provided between the first and second layers 104, 106. The semiconductor element can comprise a conductive contact pad 116 at least partially embedded in the second nonconductive or dielectric material 106, which can have a low dielectric constant k. The dielectric material 106 together with the conductive contact pad 116 forms at least part of an interconnect structure with a top bonding surface 110, which can be prepared for direct hybrid bonding to another element. The contact pad 116 connects to an underlying metallization layer 112 through an intervening via portion 114 which is narrower than the contact pad 116. In some embodiments, the contact pad 116 and via portion 114 can comprise a continuous layer formed using a dual damascene process, such that the contact pad 116 and via portion 114 are formed during the same deposition process. In this case, the via portion 114 forms part of the interconnect structure together with the contact pad 116 above and the dielectric material 106. In some embodiments, the via layer 114 is absent, and the conductive contact pad 116 is in contact with the metallization layer 112, often with the conductive barrier layer 124 disposed therebetween. In some embodiments, the conductive barrier layer 124 may wrap around or partially surround the conductive contact pad 116. The metallization layer 112 is buried in the first dielectric material layer 104, which is separated from the second dielectric material 106 by the thin etch stop layer 108. The first dielectric layer 104 and the metallization layer 112 buried therein can form part of the interconnect structure.

The contact pad 116 and the via portion 114 in FIG. 1 may be formed by a dual damascene process. During the dual damascene process, a cavity 114a for the intervening via portion 114 is etched first, followed by etching a cavity 116a for the contact pad 116. The two etching steps are normally performed by plasma etching process(es), which causes plasma damage on the sidewalls of the cavities 114a and 116a. To remove photoresist layers on the top surface 110 and organic residues on the sidewalls of the dielectric cavity after each of the etching steps, oxygen (O₂) is often used as plasma gas due to high reactivity of the O radicals. However, O₂ plasma ashing can cause detrimental damage to low-k dielectric materials. To reduce or minimize the plasma damage, a H₂-based plasma is an alternative to O₂ plasma. However, to facilitate the removal rate of photoresist with H₂-based plasma, a higher operation temperature is used, which is not preferred. To grow Cu in the cavities 114a and 116a by electroplating, a thin barrier and seeding layer (shown together by reference numeral 124) is deposited on the sidewalls and bottom surfaces. In various embodiments, the barrier layer 124 can be deposited by a physical vapor deposition (PVD) sputtering process, by atomic layer deposition (ALD) methods, or by other known methods.

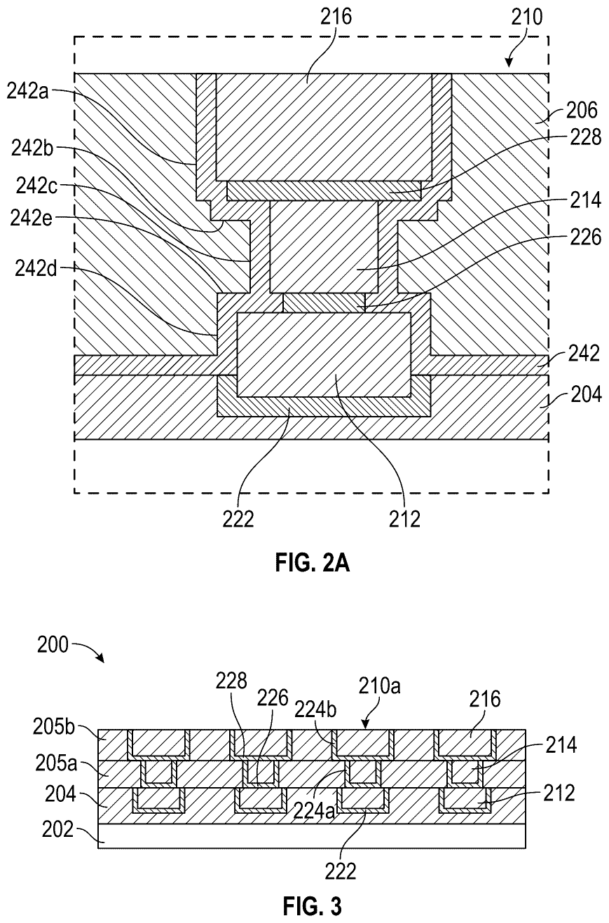

A solution to the problem of plasma damage to the low-k dielectric material in FIG. 1 is presented in FIG. 2, a schematic cross-sectional view of a semiconductor element 200. Element 200 can be a microelectronic device having active circuitry (e.g., at least one transistor), and/or passive circuitry or other devices. As shown in FIG. 2, the semiconductor element 200 comprises a substrate 202, a first dielectric layer 204, and a second dielectric layer 206 which may be separated from the first dielectric layer 204 by a thin dielectric barrier layer 242. The second dielectric layer 206 can have a low dielectric constant k to reduce the resistance capacitance (RC) delay of conductors and dielectric materials in the interconnects. Generally, a low dielectric material (or low-k material) has a dielectric constant k less than 3.9. Therefore, the dielectric constant k of the second dielectric layer 206 can be less than 3.9, for example, less than 3.5. Example low-k materials may include porous silicon oxide, organosilicate glass (SiCOH), polymeric materials, e.g., poly(arylene ether) (PAE), polyimide, polytetrafluoroethylene (PTFE, sold under the trademark TEFLON), and amorphous carbon. Some other low-k materials may have even lower dielectric constant. For example, fluorine doped amorphous carbon may have dielectric constant k in the range of 2.3-2.8.

In FIG. 2, a plurality of conductive contact pads 216 are at least partially embedded in the second low-k dielectric layer 206, forming part of an interconnect structure with a top direct hybrid bonding surface 210. A plurality of conductive features 212, as extensions of an underlying conductive layer and/or connected to underlying circuitry, are buried partially in the first dielectric layer 204 and partially in the second dielectric layer 206. The first dielectric layer 204 is disposed on a substrate 202, e.g., a semiconductor substrate (such as a silicon substrate with one or more devices formed therein or thereon). The structures disposed above the substrate 202 can be considered the interconnect structure. Each of the plurality of contact pads 216 can be connected to one or more conductive features 212 through an intervening via portion 214 buried in the second dielectric layer 206. As shown in FIG. 2, the intervening via portion 214 can have a narrower dimension in the horizontal direction than the contact pad 216 and the underlying conductive feature 212. The hybrid direct bonding surface 210 can be formed on top of the second dielectric layer 206 and the conductive contact pads 216, ready to directly bond to another semiconductor element or microelectronic device. The contact pads 216, the intervening via portions 214, and underlying conductive features 212 can each comprise a metal, e.g., copper (Cu), aluminum (Al), nickel (Ni), and tungsten (W), or non-metal conductive material, e.g., polysilicon.

One characteristic of the thin film structure shown in FIG. 2 is that each of conductor columns embedded in the second dielectric layer 206 a formed by the contact pad 216, the intervening via portion 214 and the underlying conductive feature 212 stacked connected together. Each conductor column is therefore a combined conductive features or combined conductors. Further, each of these combined conductive features or conductors is surrounded by an extended and continuous thin dielectric barrier layer 242. For example, each conductive contact pad 216 can be surrounded by a first dielectric barrier layer portion 242a at its sidewalls and by a second dielectric barrier layer portion 242b at its bottom side edges. Each of the intervening via portions 214 can be surrounded by a third dielectric barrier layer portion 242c at its sidewalls. Further, each underlying conductive feature 212 can be partially surrounded by a fourth dielectric barrier layer portion 242d at its sidewalls and by a fifth dielectric barrier layer portion 242e at its top side edges. The dielectric barrier layer portions 242a, 242b, 242c, 242d, and 242e can be connected to form a non-stop or continuous dielectric barrier layer 242, covering all sidewalls, edges, and corners of the conductive features within or exposed to the second, low-k dielectric layer 206. Therefore, the interconnect structure of the semiconductor element 200 in FIG. 2 can include the combined conductive features formed by the contact pad 216, the via portion 214 having a bottom conductive barrier layer 226 and the underlying conductive feature 212 connected together, the low-k dielectric layer 206 and the first dielectric layer 204 disposed about the combined conductive features.

FIG. 2A is a detail schematic cross-sectional view illustrating one of the four modules of combined conductive features or conductor shown in FIG. 2, magnifying the sidewall and the dielectric barrier layer 242 structures. Since the contact pads 216, the intervening via portions 214, and the underlying conductive features 212 are formed by different process steps and have different horizontal dimensions, as shown in FIG. 2A, the dielectric barrier layer 242 on a combined sidewall may not be vertically straight, but can contains vertical and horizontal sections, and inner and outer corners. Also, at the bottom of the combined sidewall the dielectric barrier layer 242 can form an approximately right angle turn extending horizontally to either reach the sidewall of another underlying conductive feature 212 or to reach an edge of the semiconductor element 200. These horizontal portion of the dielectric barrier layer 242 can be disposed at an interface between the first dielectric layer 204 and the second dielectric layer 206. The approximately right angle turn forms an L-shaped or horizontally flipped L-shaped lower portion of the dielectric barrier layer 242, as illustrated in FIG. 2A.

Another characteristic of the thin film structure in FIG. 2 and FIG. 2A is that a second thin conductive barrier layer 228 can be disposed between each connected conductive contact pad 216 and via portion 214 pair. Further, a first thin conductive barrier layer 226 is disposed between each connected via portion 214 and underlying conductive feature 212 pair. The first conductive barrier layer 226 and the second conductive barrier layer may comprise one or more of the following materials, cobalt (Co), ruthenium (Ru), tantalum (Ta), tantalum nitride (TaN), TaN/Ta multilayer, indium oxide (In2O3), tungsten nitride (WN), titanium (Ti), titanium tungsten (TiW), titanium zirconium (NiZr), titanium nitride (TiN), TiN/Ti multilayer, and various alloys and combinations formed by the above listed materials. In some embodiments, the contact pads 216 and the intervening via portions 214 can be formed by a dual damascene process. In this case, the intervening via portions 214 are formed together with the connected contact pads 216. Therefore, in other embodiments (not shown in FIG. 2), there may not be a conductive barrier between each connected contact pad 216 and via portion 214 pair.

The disclosed interconnect structure of the semiconductor element 200 shown in FIG. 2 can be formed to reduce or avoid plasma damage to the low-k dielectric layer 206. This will be demonstrated by the fabrication process for fabricating such semiconductor element 200. Certain steps of the fabrication process are illustrated in FIGS. 3-6. As shown in a schematic cross-sectional view of FIG. 3, the element 200 starts from a conventional back-end-of-line (BEOL) structure, comprising a substrate 202, a first dielectric layer 204 disposed on the substrate 202, and one or more (e.g., two) additional dielectric layers 205a and 205b disposed above the first dielectric layer 204. Each of the three dielectric layers 204, 205a and 205b may comprise a non-low-k dielectric material, e.g., silicon oxide. In other embodiments, the layers 204, 205a, 205b can comprise a single dielectric layer. As explained above, a plurality of underlying conductive features 212 can be buried in the first dielectric layer 204. A plurality of conductive contact pads 216 can be at least partially embedded in the top dielectric layer 205b. In the middle dielectric layer 205a, a plurality of via portions 214 extend through the thickness of the layer, each connecting to a contact pad 216 above and to an underlying conductive feature 212 below. In some embodiments, the contact pads 216 and the intervening via portions 214 may be formed by a dual damascene process. In such a case, the dielectric layers 205a and 205b can comprise one dielectric layer, and each conductive pad 216 and the connected via portion 214 underneath are formed together without a separation layer between them. The top surface 210a comprises the dielectric material 205b and conductive contact pads 216. In some embodiments, the semiconductor element 200 comprises more than one underlying conductive layers having extended underlying conductive features. For example, when two underlying conductive layers are disposed in the semiconductor element 200 with contact pads in a top interconnecting bonding layer, there may exist five dielectric layers, including the layers for via portions connecting the conductive features of the different conductive layers.

As shown in FIG. 3, in each dielectric layer, e.g., silicon oxide (SiO₂), the conductive features are surrounded by a thin conductive barrier layer and in various embodiments another seeding layer. In the first dielectric layer 204, the underlying conductive features 212 are surrounded by a thin conductive barrier layer 222 at the sidewalls and the bottom surface. In the middle dielectric layer 205a, the intervening via portions 214 are surrounded by a thin conductive barrier layer portion 224a at its sidewalls and a first thin conductive barrier layer portion 226 at its bottom surface. The thin barrier layer portions 224a and 226 are deposited together. As such they are connected forming a continuous barrier layer. In the top dielectric layer 205b, the conductive contact pads 216 are surrounded by a thin barrier layer portion 224b at its sidewalls and a second thin conductive barrier layer portion 228 at its bottom surface. Likewise, the thin barrier layer portions 224b and 228 are connected forming a continuous barrier layer. As disclosed previously, the conductive barrier layer portions 224a and 226, surrounding the via portions 214 and the conductive barrier layer portions 224b and 228 surrounding the contact pads 216 may comprise one or more of the following materials, cobalt (Co), ruthenium (Ru), tantalum (Ta), tantalum nitride (TaN), TaN/Ta multilayer, indium oxide (In2O3), tungsten nitride (WN), titanium (Ti), titanium tungsten (TiW), titanium zirconium (NiZr), titanium nitride (TiN), TiN/Ti multilayer, and various alloys and combinations formed by the above listed materials. These thin conductive barrier layers can be provided to impede the diffusion of the conductive material into the dielectric material. In some embodiments, another seeding layer is disposed between the barrier layer and the surrounded conductive feature to initiate the growth of the corresponding conductive material.

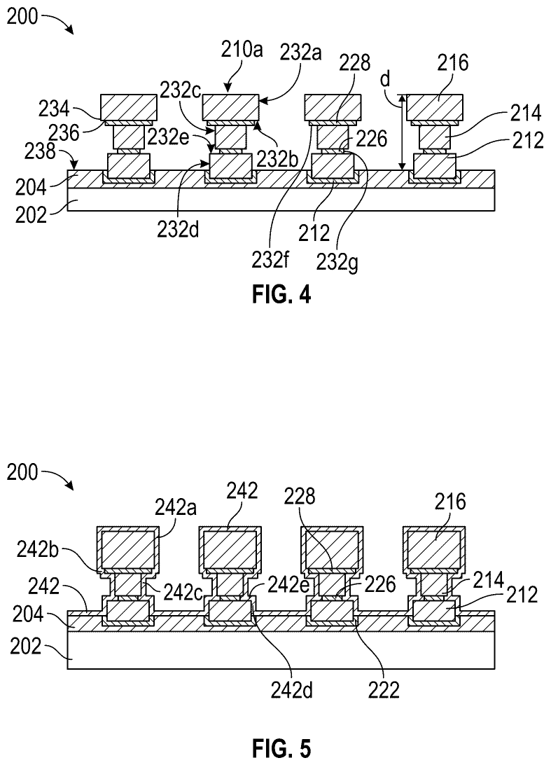

In FIG. 4, an etching process, e.g., a selective fluoride ion plasma reactive ion etching (RIE) process, can be performed to remove the dielectric layers 205b and 205a, and a top portion of the first dielectric layer 204. In some embodiments, portions of the dielectric layer 205b are removed. In some embodiments, the dielectric layer 205b and portions of dielectric 205a are removed. The etching process may also remove all or portions of the conductive barrier layer portions 222, 224a, 224b, 226 and 228. The materials to be etched and the etching depth d, as depicted in FIG. 4, can be determined by the etching method, a barrier layer material, or etching time, etc. As such, sidewalls 232a and bottom edges 232b of contact pads 216 and sidewalls 232c of the intervening via portions 214 are exposed. More exposed areas include sidewalls 232d that extends a partial thickness of the underlying conductive features 212 and top edges 232e of the underlying conductive features 212. Further, the conductive barrier portions 228, 226 at the lower surfaces 232b of the contact pads 216 and at the lower surfaces of the intervening via portions 214 are partially removed from outside edges, creating undercuts 232f, 232g in both places. Since the intervening via portions 214 usually have narrower cross-section width than the contact pad 216 above and the underlying conductive feature 212 below, the sidewalls of each connected conductive feature, formed by the contact pad 216, the intervening via portion 214 and the underlying conductive feature 212 in sequence, are not vertically straight, but have approximate right angle corners. As illustrated in FIG. 4, the exposed combined sidewalls 232, including 232a, 232b, 232c, 232d, 232c, 232f, and 232g have vertical sidewall sections, horizontal sections, with outer corners (e.g., outer corner 234) and inner corners (e.g., inner corner 236) between them. Sidewall 232d, as lower portion of each combined sidewall 232, meets a top surface 238 of the unetched first dielectric layer 204, forming an approximately right angle turn. The top surface 238 of the unetched first dielectric layer 204 can cover the areas between adjacent conductive features 212 and the areas from the outer conductive features 212 to the edge of the semiconductor element 200. After the removal of the dielectric layer 205b or layers 205b and 205a, the exposed etched surfaces may be cleaned, to strip off organic materials residue which is typically the byproduct of the etching step. In some applications, the cleaning process may comprise rinsing the substrate with alkaline solutions or vapor to strip off the organic residues. The cleaned surface may be rinsed with DI water or other solvent and dried.

Referring to FIG. 5, a nonconductive dielectric barrier layer 242 is deposited on the exposed surfaces of the semiconductor element 200 shown in FIG. 4, including the top surfaces 210a, the sidewalls 232a and portions of the bottom surfaces 232b of the conductive contact pads 216, the sidewalls 232c of the intervening via portions 214, the sidewalls 232d, portions of the top surfaces 232e of the underlying conductive features 212, the exposed edges 232f, 232g of the conductive barrier layers 226 and 228, and the exposed top surface 238 of the first dielectric layer 204. Therefore, the nonconductive dielectric barrier layer 242 includes the thin dielectric barrier layer portions 242a coated on the sidewalls 232a, the thin dielectric barrier layer portions 242b on the bottom surfaces 232b of the conductive contact pads 216, the thin dielectric barrier layer portions 242c on the sidewalls 232c of the intervening via portions 214, the thin dielectric barrier layer portions 242d on the sidewalls 232d, the thin dielectric barrier layer portions 242e on the top surface 232e of the underlying conductive features 212, the horizontal portions 242 covering the top surface 210a on the contact pad 216, and other horizontal portions 242 covering the top surface 238 on the first dielectric layer 204. Both the outer corners 234 and the inner corners 236 can be covered by the thin nonconductive barrier 242 as well.

Since the sidewalls 232 of the combined conductive features 212, 214 and 216 may not be vertically straight, but with turns and corners, including outer corners, e.g., 234, and inner corners, e.g., 236, the thin nonconductive dielectric barrier layer 242 coated on the sidewalls 232 may also not be vertically straight, and are characterized by turns and corners. At the bottom of each sidewall 232, the thin dielectric barrier layer 242 can form an approximately right angle (e.g., 90°) Corner, or about square corner, and extends to cover the top surface 238 of the first dielectric layer 204. The approximately right angle corner of the dielectric barrier layer between the sidewall 232 and the top surface 238 can be L-shaped, or horizontally flipped L-shaped. The nonconductive dielectric barrier layer 242 may be made of, e.g., AlₓO_{y} or ZrₓO_{y}, SIN, SiC, SiCN, SiO2, or SiON material, and may be deposited by an atomic layer deposition (ALD), a plasma-enhanced atomic layer deposition (PEALD), or a chemical vapor deposition (CVD) method at a temperature lower than 200° C. In some embodiments, the deposition temperature may be lower than 150° C., for example, lower than 100° C. The nonconductive barrier layer 242 may not be stoichiometric in composition.

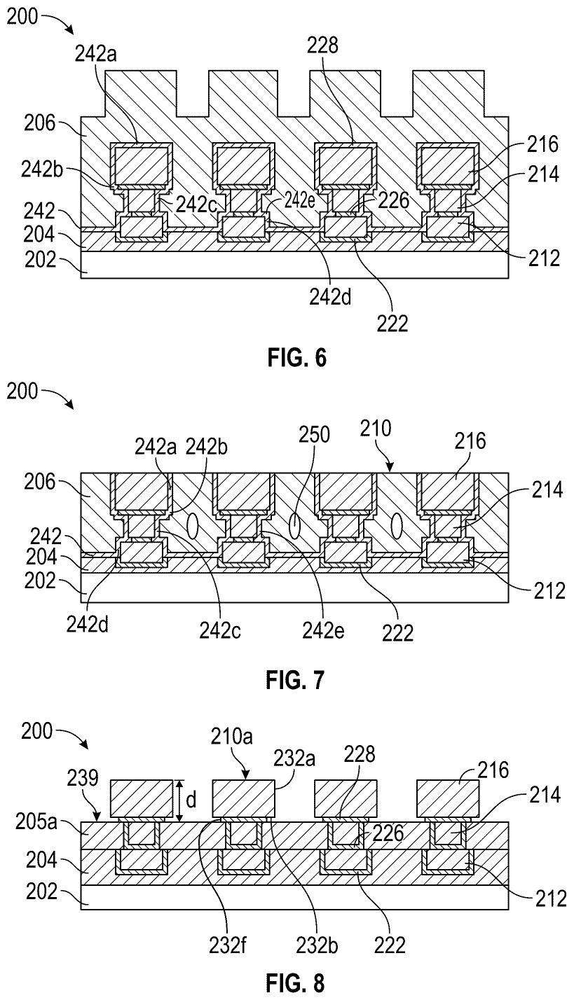

In FIG. 6, the semiconductor element 200 is coated with a low-k dielectric material 206, filling gaps between the conductive features and overfilling above the top of the contact pads 216. The dielectric constant k of the low-k dielectric material 206 may be less than 3.5, e.g., less than 3.0. Such low-k materials may include porous silicon oxide, organosilicate glass (SiCOH), polymeric materials, e.g., poly(arylene ether) (PAE), polyimide, polytetrafluoroethylene (PTFE, sold under the trademark TEFLON), and amorphous carbon. The low k coating process may comprise an ALD method, PVD methods, a spin on dielectric method, evaporative methods, and lamination methods amongst others. After the coating step, the top portion of the low-k dielectric material 206 is removed and planarized by a chemical mechanical process (CMP) to form a direct hybrid bonding surface 210, as shown in FIG. 2 and described above. Beneficially, during the process of coating the low-k dielectric material 206, the low-k dielectric material 206 may not be exposed to plasma reactive ion etching (RIE) plasma. As such, no plasma damage is caused in the low-k dielectric material 206, e.g., along sidewalls of the low-k dielectric material 206. The hybrid bonding surface 210 may be further processed (including by a plasma activation) to prepare for direct hybrid bonding. The preparation steps may include rinsing the activated bonding surface with DI water or other suitable solvents, and drying the rinsed bonding surface.

As the low-k dielectric layer 206 is deposited after the conductive features 212, 214 and 216 are formed, the deposition method may leave voids in the low-k dielectric layer 206. In each combined conductive feature, including a contact pad 216, an intervening via portion 214 and an underlying conductive feature 212, the middle portion formed by the intervening via portion 214 may be narrower than the conductive feature 212 below and the contact pad 216 above. This means that the combined conductive feature may have indented or concaved sidewalls. Therefore, the gap between middle sidewall portions 232c may be wider than the top portions 232as and the bottom portion 232ds of the sidewalls 232. When the low-k dielectric material 206 is deposited, it may grow from all surfaces, including the portions of the sidewalls 232, the top surface 238 of the first dielectric layer 204, and the top surface 210a of the contact pads 216 approximately simultaneously and approximately uniformly. In this way, the gap between the top sidewalls 232a may be filled up before the gaps between middle sidewalls 232c, leaving voids 250 in the spaces between the adjacent via portions 214, as shown in FIG. 7. Further, in some embodiments, on or just below the top bonding surface 210 there may exist porosity and small voids which may impose negative impact on direct bonding of the semiconductor element 200 to another element or device. This negative impact will be addressed as explained herein in connection with FIG. 14.

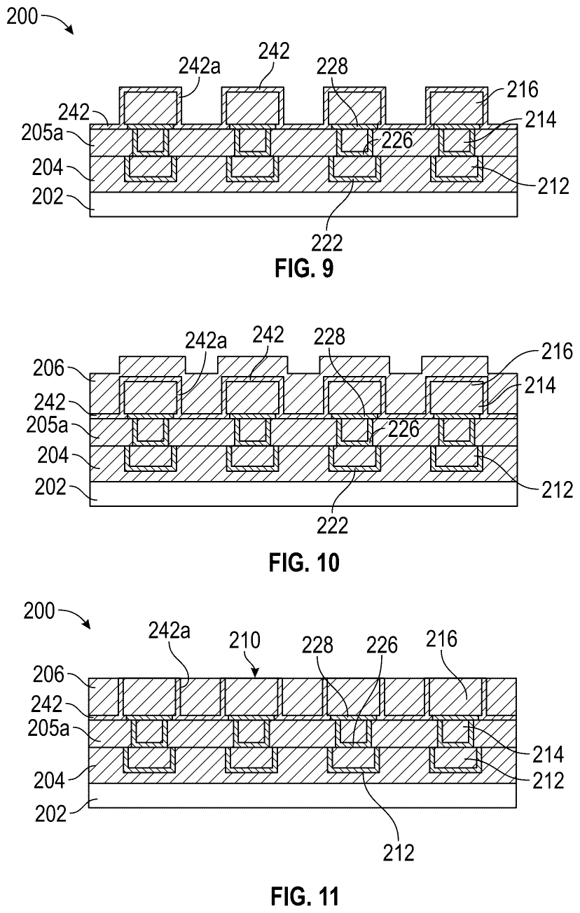

In some embodiments, the etching in of FIG. 4 may be performed to reach a predetermined etching depth d. In some embodiments, the etching depth d. can reach the top surface of the first dielectric layer 214. In some embodiments, for example, the selective fluoride ion plasma reactive ion etching (RIE) may be performed to remove the top dielectric layers 205b only, not the middle dielectric layer 205a, or at least not entirely. As shown in FIG. 8, the etching depth d may be performed deep enough to expose the entire sidewall section 232a, and undercut the second thin conductive barrier layer portion 228 between the contact pads 216 and the intervening via portions 214 to expose the edge 232f. A top surface 239 is formed on the middle dielectric layer 205a. In FIG. 9, the thin dielectric or nonconductive layer 242 is coated on the sidewalls 232 (232a and 232b), the top surface 239 of the middle dielectric layer 205a, and the top surface 210a of the contact pads 216, similar to the deposition method described with FIG. 5 above. The difference is that the sidewalls 242a shown in FIG. 9 may be approximately vertical and straight and without the corners like in the middle portions of the sidewall portions 242a, 242b, 242c, 242d, and 242e shown in FIG. 5. However, similar to the lower sidewall portions illustrated in FIG. 5, the lower portion of each sidewall 242 in FIG. 9 is characterized by an approximately right angle turn, extending to cover the top surface 239 of the middle dielectric layer 205a. When the side edge 232f is deposited with the nonconductive layer 242, small dent may form due to undercut. The thickness of the conductive barrier layer 228 may be in the same order of the thickness of the nonconductive layer 242. As such, the dent may be small and in significant compared to the is dimensions of the dielectric layers 205a or 205b. In some embodiments, the side wall portion 242a of the conductive contact pad 216 may be tapered away from an imaginary vertical plane disposed at the side walls of the conductive contact pad 216. The taper of the side wall may be such that the distance between the top side walls of adjacent contact pads 216 is smaller than the distance between the bottom side walls of two adjacent contact pads 216. In some embodiments, the angle of taper of the side walls 242a (measured from a horizontal plane) may range between 90.5° and 105.5°, for example, between 91° and 100°, or between 91.5° and 95°.

In FIG. 10, a low-k dielectric material 206 is disposed in spaces between the conductive contact pads 216 to overfill the spaces between and above the contact pads 216, similar to the process described with FIG. 6. In FIG. 11, the excess low-k dielectric material 206, and optionally part of the top portions of the contact pads 216, can be removed and planarized, e.g., by chemical mechanical polishing (CMP). As shown in FIG. 11, the dielectric barrier layer 242 surrounds only the contact pads 216, not reaching the intervening vias 214 and the underlying conductive features 212. As such, the combined conductive features defined above with FIGS. 2-7 only comprise the contact pads 216 in FIG. 11. The horizontal sections of the nonconductive barrier layer 242 are above the middle dielectric layer 205a. The vertical sections and the horizontal sections of the dielectric barrier layer 242 meet to form approximately right angle or L-shaped turn at the bottom of each sidewall 232. For the semiconductor element 200 in FIG. 11, the interconnect structure comprises the contact pads 216, the low-k dielectric layer 206 disposed about the contact pads 216, and the first dielectric layer 204 disposed about the conductive structures.

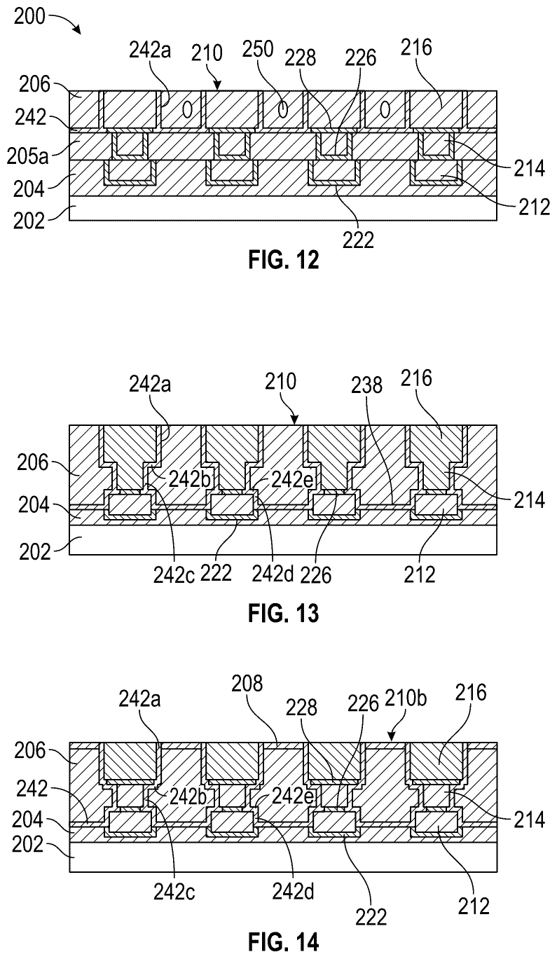

Similar to FIG. 2, each contact pad 216 to via portion 214 connection in FIG. 11 may be separated by a second thin conductive barrier layer 228, and each via portion 214 to the underlying conductive feature connection may be separated by a first thin conductive barrier layer 226. Similar to the illustration in FIG. 7 above, the low-k dielectric layer 206 may be porous and may contain small voids 250 which may have a negative impact on direct bonding of the semiconductor element 200 to another element or device, as shown in FIG. 12.

As described with respect to FIG. 2 above, in some embodiments, the conductive contact pads 216 and the intervening via portions 214 may be formed by the dual damascene process. As such each contact pad 216 can be formed together with the connected via portion 214 underneath with a uniform conductive material, such that there may be no conductive barrier layer between them. Following the process steps of FIGS. 5-6 and the step of planarization, a cross-sectional structure schematically illustrated in FIG. 13 is obtained for such a semiconductor element 200. In FIG. 13, due to the dual damascene process, there is no conductive barrier layer 228 between the pad 216 and via portion 214 as compared with FIG. 2. The nonconductive barrier layer 242 can have similar characteristics as the structure of FIG. 2, e.g., inner and outer corners and L-shaped bottom portion between each sidewall section and the connected horizontal section on the top surface 238 of the first dielectric layer 204. In some embodiments, the inner and outer corners and the L-shaped turns, e.g., the corner between the sidewall section 242a and the connected horizontal section 242b, may be rounded. In some embodiments, the radius of the rounded corner at the intersection of the side wall 242a and the horizontal section 242b is less than a width of the conductive contact pad 216.

As described above with FIG. 7 and FIG. 12, porosity and small voids may exist in the low-k dielectric layer 206, which may have a negative effect on the bonding quality when the semiconductor 200 is directly bonded to another element or device, and/or on the electrical characteristics of the device. In some embodiments, the top bonding surface 210 may be modified for enhanced direct bonding quality. In FIG. 14, a thin top dielectric layer 208 is deposited on the low-k dielectric layer 206, and planarized. The finished top surface 210b can be compact and smooth, and may be configured for high quality direct bonding. The top dielectric layer 208 may comprise a non-low-k dielectric material, e.g., silicon oxide (SiO2), silicon nitride (SiN), or silicon carbon nitride (SiCN). The material for the top dielectric layer 208 may not be the same of the material for the first dielectric layer 204.

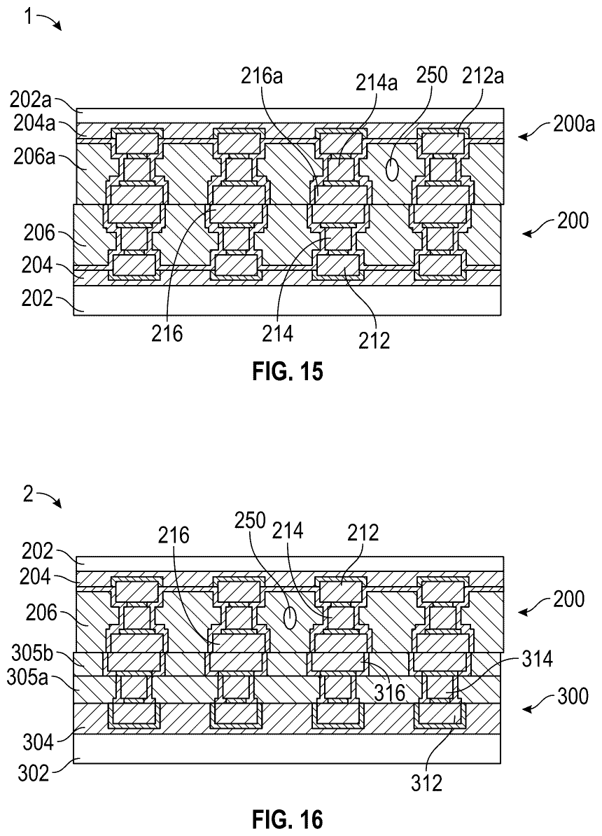

Referring to FIG. 15, a bonded structure 1 comprises two semiconductor elements 200 and 200a, each with a low-k dielectric material in its bonding layer. The semiconductor 200 includes the low-k dielectric material 206 in the bonding layer, while the semiconductor 200a includes a low-k dielectric material 206a in its bonding layer. When directly bonded, portions of the low-k dielectric material 206 of the element 200 can be directly bonded to corresponding portions of the low-k dielectric material 206a of the element 200a. Further, each contact pad 216 of the element 200 can be directly bonded to a corresponding contact pad 216a of the element 200a. The bonding process may be performed at room temperature, and subsequently annealed at an elevated temperature.

In FIG. 16, a bonded structure 2 comprises two semiconductor elements 200 and 300. While the element 200 includes the low-k dielectric material 206 in the bonding layer, as reflected in FIG. 2, the element 300 is produced with a conventional BEOL structure, including a non-low-k dielectric material 306 in its bonding layer, similar to the semiconductor element 200 shown in FIG. 3. When directly bonded, portions of the low-k dielectric material 206 of the element 200 are directly bonded to corresponding portions of the non-low-k dielectric material 306 of the element 300. Further, each contact pad 216 of the element 200 can be directly bonded to a corresponding contact pad 316 of element 300.

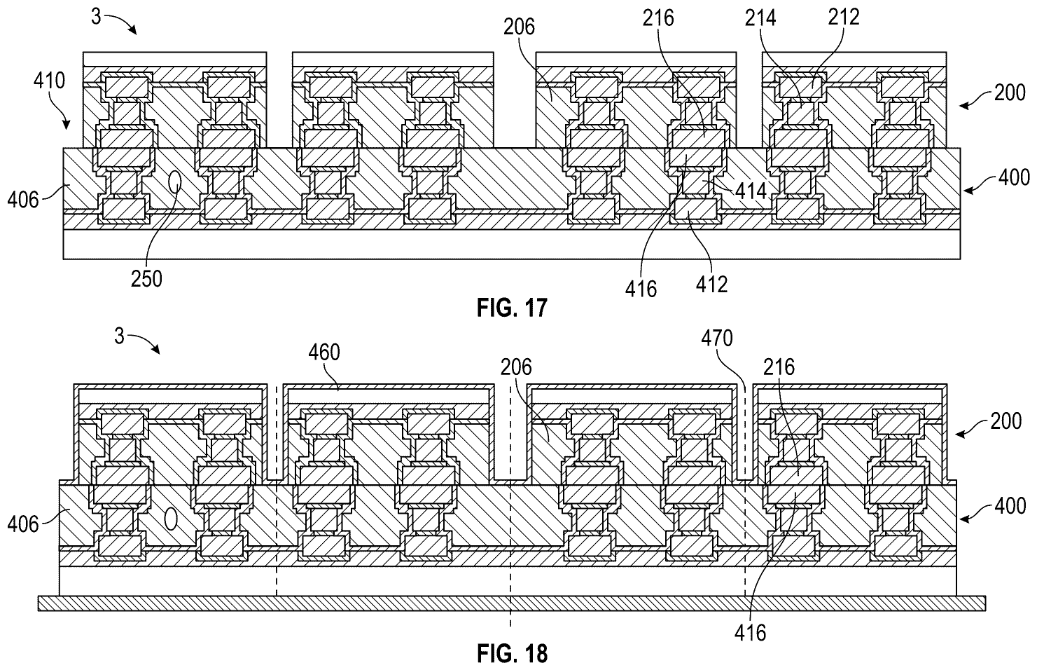

FIG. 17 schematically illustrates direct bonding of a plurality of dies, e.g., the semiconductor element 200 of FIG. 2, to a wafer 400 having a plurality of semiconductor modules, e.g., a die-to-wafer (D2W) assembly, forming a bonded structure 3. The wafer 400 may comprise conductive contact pads 416 embedded in a low-k dielectric bonding layer 406, forming a bonding surface 410. Each contact pad 416 is connected to an underlying conductive feature 416 through an intervening via portion 414. When directly bonded, portions of the low-k dielectric material 206 of each element 200 can be directly bonded to corresponding portions of the non-low-k dielectric material 406 of the wafer 400. Further, each contact pad 216 of the element 200 can be directly bonded to a corresponding contact pad 416 of wafer 400. The bonding process may be performed at a higher temperature so that the opposing respective conductive contact pads can be mechanically fused together to be electrically connected.

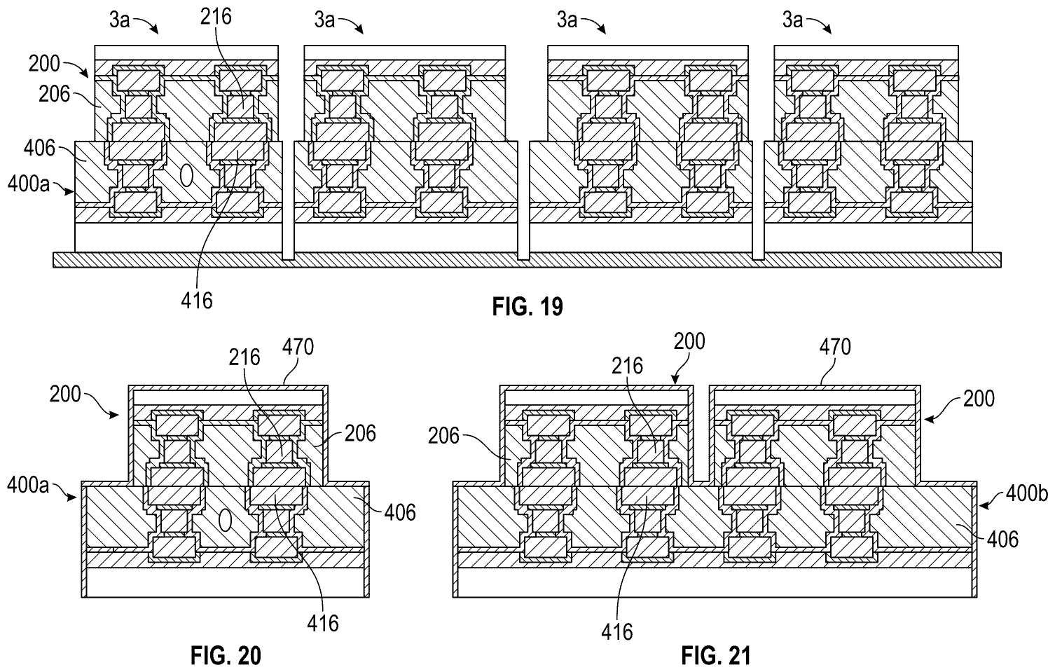

In FIG. 18, the directly bonded structure 3 is coated with a protective layer 460 over the exposed surfaces, including the upper and side surfaces of the element dies 200 on top and the exposed upper portions of the lower wafter 400. The protective layer 460 can comprise an organic insulating material (such as a photoresist) to protect the dies during singulation. The bonded structure 3 can be singulated between adjacent semiconductor elements 200, as indicated by the broken lines 470 shown in FIG. 18. The singulation method may be mechanical dicing, e.g., using a saw blade, laser dicing, or plasma etching. As FIG. 19 illustrates, after singulation, the protective layer 460 can be stripped and the bonded structure can be cleaned and dried. The resulting bonded structure 3 can be singulated into a plurality of bonded structures 3a, each having one semiconductor element 200. As shown in FIGS. 20 and 21, the singulated bonded structure can be encapsulated with an ALD coated barrier or encapsulating layer 470 for protection. The encapsulating layer 470 can comprise an inorganic layer (such as silicon oxide, silicon nitride, etc.) in some embodiments. In some embodiments, the encapsulating layer 470 can comprise multiple dielectric (e.g., inorganic dielectric) sub-layers. In other embodiments, the encapsulating layer 470 can comprise one or more organic insulating layers. FIG. 20 shows a singulated structure with one semiconductor element 200. FIG. 21 shows a singulated structure with two semiconductor elements 200. Any suitable number of semiconductor elements 200 can be provided.

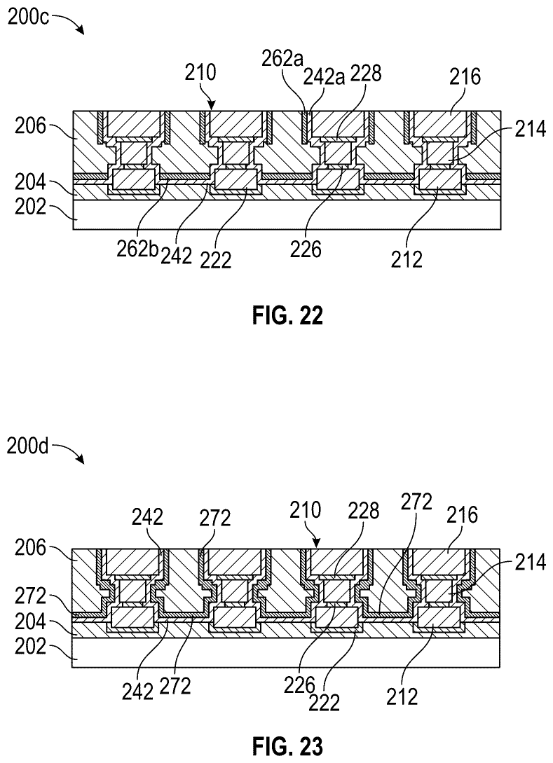

The semiconductor element 200 can also be protected against electromagnetic interference (EMI) by a Faraday cage, which may be formed by an embedded thin conductive layer provided around conductive features. Such Faraday cage solutions are schematically illustrated in FIG. 22 and FIG. 23. In FIG. 22, a semiconductor element 200c comprises the features of the semiconductor element 200 shown in FIG. 2, including the substrate 202, the first dielectric layer 204, the low-k dielectric layer 206, and the contact pads 216 connected with the underlying conductive features 212 with via portions 214. A thin dielectric barrier layer 242 separates the conductive features and the low-k dielectric material 206. Furthermore, the semiconductor element 200c can include a thin conductive layer 262a outside the sidewall dielectric barrier layers 242a surrounding the contact pads 216, and a thin conductive layer 262b above the dielectric barrier layer 242 on top of the first dielectric layer 204. The thin conductive layers 262a and 262b can form a Faraday cage surrounding each conductive feature in the semiconductor 200c so as to provide a shield against EMI.

In FIG. 23, a semiconductor element 200d is structured similar to the semiconductor 200c, except that a thin conductive layer 272 is coated on the entire (or substantially the entire) dielectric barrier layer 242. The coating of the conductive layer 272 may be conducted after the step of FIG. 5 for depositing the dielectric barrier layer 242 and before the step of FIG. 6 for coating the low-k dielectric layer 206. Since the conductive layer 272 is deposited on the dielectric barrier layer 242, the conductive layer 272 may have geometric characteristics similar to those of the dielectric barrier layer 242, e.g., the continuous vertical sections with corners and an approximately right angle turn at the bottom to extend horizontally. As demonstrated in FIG. 23, the conductive layer 272 can encage each combined conductive feature comprising a contact pad 216, an intervening via portion 214 and an underlying conductive feature 212, thus forming a Faraday cage. The Faraday cage efficiently blocks EMI from circuitry within the element or external electrical devices, and from potentially harmful radio frequencies. The semiconductor element of FIG. 23 comprising a Faraday cage 272 around each combined conductive feature 216, 214 and 212 may be singulated and bonded to another element or structure as described above in the form of wafer-to-wafer (W2W) or die-to-wafer (D2W). The bonded structure may be annealed at a higher temperature, prior to subsequent processing. The subsequent processing may comprise bonding additional substrate to the bonded structures, encapsulations steps, and further singulations, amongst others.

### Electronic Elements

A die can refer to any suitable type of integrated device die. For example, the integrated device dies can comprise an electronic component such as an integrated circuit (such as a processor die, a controller die, or a memory die), a microelectromechanical systems (MEMS) die, an optical device, or any other suitable type of device die. In some embodiments, the electronic component can comprise a passive device such as a capacitor, inductor, or other surface-mounted device. Circuitry (such as active components like transistors) can be patterned at or near active surface(s) of the die in various embodiments. The active surface may be on a side of the die which is opposite the backside of the die. The backside may or may not include any active circuitry or passive devices.

An integrated device die can comprise a bonding surface and a back surface opposite the bonding surface. The bonding surface can have a plurality of conductive bond pads including a conductive bond pad, and a non-conductive material proximate to the conductive bond pad. In some embodiments, the conductive bond pads of the integrated device die can be directly bonded to the corresponding conductive pads of the substrate or wafer without an intervening adhesive, and the non-conductive material of the integrated device die can be directly bonded to a portion of the corresponding non-conductive material of the substrate or wafer without an intervening adhesive. Directly bonding without an adhesive is described throughout U.S. Pat. Nos. 7,126,212; 8,153,505; 7,622.324; 7,602,070; 8,163,373; 8,389,378; 7,485,968; 8,735,219; 9,385,024; 9,391,143; 9,431,368; 9,953,941; 9,716,033; 9,852,988; 10,032,068; 10,204,893; 10,434,749; and 10,446,532, the contents of each of which are hereby incorporated by reference herein in their entirety and for all purposes.

### Examples of Direct Hybrid Bonding Methods and Directly Bonded Structures

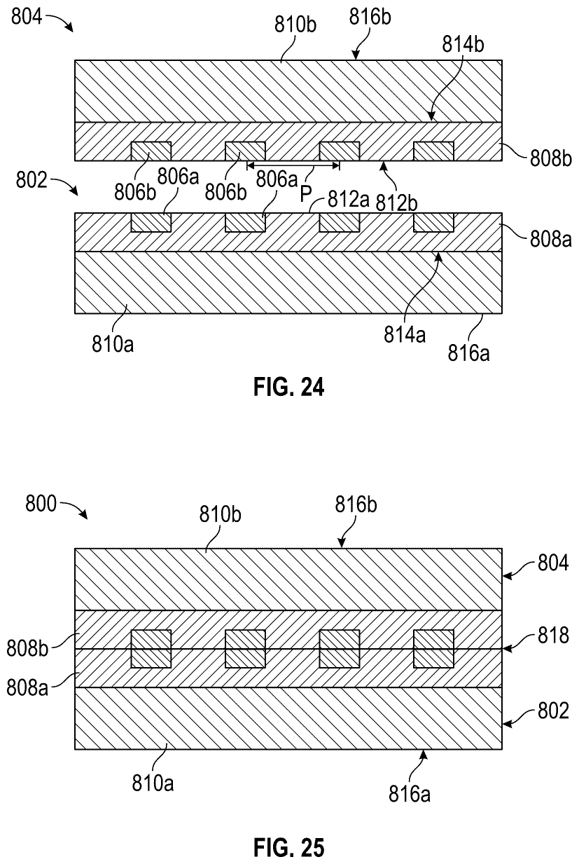

Various embodiments disclosed herein relate to directly bonded structures in which two elements can be directly bonded to one another without an intervening adhesive. FIGS. 24 and 25 schematically illustrate a process for forming a directly hybrid bonded structure without an intervening adhesive according to some embodiments. In FIGS. 24 and 25, a bonded structure 800 comprises two elements 802 and 804 that can be directly bonded to one another at a bond interface 818 without an intervening adhesive. Two or more microelectronic elements 802 and 804 (such as semiconductor elements, including, for example, integrated device dies, wafers, passive devices, individual active devices such as power switches, etc.) may be stacked on or bonded to one another to form the bonded structure 800. Conductive features 806a (e.g., contact pads, exposed ends of vias (e.g., TSVs), or a through substrate electrodes) of the first element 802 may be electrically connected to corresponding conductive features 806b of the second element 804. Any suitable number of elements can be stacked in the bonded structure 800. For example, a third element (not shown) can be stacked on the second element 804, a fourth element (not shown) can be stacked on the third element, and so forth. Additionally, or alternatively, one or more additional elements (not shown) can be stacked laterally adjacent one another along the first element 802. In some embodiments, the laterally stacked additional element may be smaller than the second element. In some embodiments, the laterally stacked additional element may be two times smaller than the second element.

In some embodiments, the elements 802 and 804 are directly bonded to one another without an adhesive. In various embodiments, a non-conductive field region that includes a non-conductive or dielectric material can serve as a first bonding layer 808a of the first element 802 which can be directly bonded to a corresponding non-conductive field region that includes a non-conductive or dielectric material serving as a second bonding layer 808b of the second element 804 without an adhesive. The non-conductive bonding layers 808a and 808b can be disposed on respective front sides 814a and 814b of device portions 810a and 810b, such as a semiconductor (e.g., silicon) portion of the elements 802 and 804. Active devices and/or circuitry can be patterned and/or otherwise disposed at or near the front sides 814a and 814b of the device portions 810a and 810b, and/or at or near opposite backsides 816a and 816b of the device portions 810a and 810b. Bonding layers can be provided on front sides and/or back sides of the elements. The non-conductive material can be referred to as a non-conductive bonding region or bonding layer 808a of the first element 802. In some embodiments, the non-conductive bonding layer 808a of the first element 802 can be directly bonded to the corresponding non-conductive bonding layer 808b of the second element 804 using dielectric-to-dielectric bonding techniques. For example, non-conductive-to-non-conductive or dielectric-to-dielectric bonds may be formed without an adhesive using the direct bonding techniques disclosed at least in U.S. Pat. Nos. 9,564,414; 9,391,143; and 10.434,749, the entire contents of each of which are incorporated by reference herein in their entirety and for all purposes. It should be appreciated that in various embodiments, the bonding layers 808a and/or 808b can comprise a non-conductive material such as a dielectric material, e.g., silicon oxide, or an undoped semiconductor material, e.g., undoped silicon. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials do not comprise polymer materials, such as epoxy, resin or molding materials.

In some embodiments, the device portions 810a and 810b can have a significantly different coefficients of thermal expansion (CTEs) defining a heterogenous structure. The CTE difference between the device portions 810a and 810b, and particularly between bulk semiconductor, typically single crystal portions of the device portions 810a. 810b, can be greater than 5 ppm or greater than 10 ppm. For example, the CTE difference between the device portions 810a and 810b can be in a range of 5 ppm to 100 ppm, 5 ppm to 40 ppm, 10 ppm to 100 ppm, or 10 ppm to 40 ppm. In some embodiments, one of the device portions 810a and 810b can comprise optoelectronic single crystal materials, including perovskite materials, that are useful for optical piezoelectric or pyroelectric applications, and the other of the device portions 810a, 810b can comprise a more conventional substrate material. For example, one of the device portions 810a, 810b comprises lithium tantalate (LiTaO₃) or lithium niobate (LiNbO₃), and the other one of the device portions 810a, 810b comprises silicon (Si), quartz, fused silica glass, sapphire, or a glass. In other embodiments, one of the device portions 810a and 810b comprises a III-V single semiconductor material, such as gallium arsenide (GaAs) or gallium nitride (GaN), and the other one of the device portions 810a and 810b can comprise a non-III-V semiconductor material, such as silicon (Si), or can comprise other materials with similar CTE, such as quartz, fused silica glass, sapphire, or a glass.

In various embodiments, direct hybrid bonds can be formed without an intervening adhesive. For example, nonconductive bonding surfaces 812a and 812b can be polished to a high degree of smoothness. The nonconductive bonding surfaces 812a and 812b can be polished using, for example, chemical mechanical polishing (CMP). The roughness of the polished bonding surfaces 812a and 812b can be less than 30 Å rms. For example, the roughness of the bonding surfaces 812a and 812b can be in a range of about 0.1 Å rms to 15 Å rms, 0.5 Å rms to 10 Å rms, or 1 Årms to 5 Å rms. The bonding surfaces 812a and 812b can be cleaned and exposed to a plasma and/or etchants to activate the surfaces 812a and 812b. In some embodiments, the surfaces 812a and 812b can be terminated with a species after activation or during activation (e.g., during the plasma and/or etch processes). Without being limited by theory, in some embodiments, the activation process can be performed to break chemical bonds at the bonding surfaces 812a and 812b, and the termination process can provide additional chemical species at the bonding surfaces 812a and 812b that improves the bonding energy during direct bonding. In some embodiments, the activation and termination are provided in the same step, e.g., a plasma to activate and terminate the surfaces 812a and 812b. In other embodiments, the bonding surfaces 812a and 812b can be terminated in a separate treatment to provide additional species for direct bonding. In various embodiments, the terminating species can comprise nitrogen. For example, in some embodiments, the bonding surface(s) 812a. 812b can be exposed to a nitrogen-containing plasma. Further, in some embodiments, the bonding surfaces 812a and 812b can be exposed to fluorine. For example, there may be one or multiple fluorine peaks at or near a bond interface 818 between the first and second elements 802, 804. Thus, in the directly bonded structure 800, the bond interface 818 between two non-conductive materials (e.g., the bonding layers 808a and 808b) can comprise a very smooth interface with higher nitrogen content and/or fluorine peaks at the bond interface 818. Additional examples of activation and/or termination treatments may be found int U.S. Pat. Nos. 9,564,414; 9,391,143; and 10,434,749, the entire contents of each of which are incorporated by reference herein in their entirety and for all purposes. The roughness of the polished bonding surfaces 812a and 812b can be slightly rougher (e.g., about 1 Å rms to 30 Å rms, 3 Å rms to 20 Å rms, or possibly rougher) after an activation process.

In various embodiments, conductive features 806a of the first element 802 can also be directly bonded to corresponding conductive features 806b of the second element 804. For example, a direct hybrid bonding technique can be used to provide conductor-to-conductor direct bonds along the bond interface 818 that includes covalently direct bonded non-conductive-to-non-conductive (e.g., dielectric-to-dielectric) surfaces, prepared as described above. In various embodiments, the conductor-to-conductor (e.g., conductive feature 806a to conductive feature 806b) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes. In direct hybrid bonding embodiments described herein, conductive features are provided within non-conductive bonding layers, and both conductive and nonconductive features are prepared for direct bonding, such as by the planarization, activation and/or termination treatments described above. Thus, the bonding surface prepared for direct bonding includes both conductive and non-conductive features.

For example, non-conductive (e.g., dielectric) bonding surfaces 812a, 812b (for example, inorganic dielectric surfaces) can be prepared and directly bonded to one another without an intervening adhesive as explained above. Conductive contact features (e.g., conductive features 806a and 806b which may be at least partially surrounded by non-conductive dielectric field regions within the bonding layers 808a, 808b) may also directly bonded to one another without an intervening adhesive. In various embodiments, the conductive features 806a, 806b can comprise discrete pads or traces at least partially embedded in the non-conductive field regions. In some embodiments, the conductive contact features can comprise exposed contact surfaces of through substrate vias (e.g., through silicon vias (TSVs)). In some embodiments, the respective conductive features 806a and 806b can be recessed below exterior (e.g., upper) surfaces (non-conductive bonding surfaces 812a and 812b) of the dielectric field region or non-conductive bonding layers 808a and 808b, for example, recessed by less than 30 nm, less than 20 nm, less than 15 nm, or less than 10 nm, for example, recessed in a range of 2 nm to 20 nm, or in a range of 4 nm to 10 nm. In various embodiments, prior to direct bonding, the recesses in the opposing elements can be sized such that the total gap between opposing contact pads is less than 15 nm, or less than 10 nm. The non-conductive bonding layers 108a and 108b can be directly bonded to one another without an adhesive at room temperature in some embodiments and, subsequently, the bonded structure 100 can be annealed. Upon annealing, the conductive features 106a and 106b can expand and contact one another to form a metal-to-metal direct bond. Beneficially, the use of Direct Bond Interconnect, or by the trademark DBI®, techniques commercially available from Adeia of San Jose, CA, can enable high density of conductive features 806a and 806b to be connected across the direct bond interface 818 (e.g., small or fine pitches for regular arrays). In some embodiments, the pitch, P, of the conductive features 806a and 806b, such as conductive traces embedded in the bonding surface of one of the bonded elements, may be less than 100 microns or less than 10 microns or even less than 2 microns. For some applications, the ratio of the pitch of the conductive features 806a and 806b to one of the dimensions (e.g., a diameter) of the bonding pad is less than is less than 20, or less than 10, or less than 5, or less than 3 and sometimes desirably less than 2. In other applications, the width of the conductive traces embedded in the bonding surface of one of the bonded elements may range between 0.3 to 20 microns, e.g., in a range of 0.3 to 3 microns. In various embodiments, the conductive features 806a and 806b and/or traces can comprise copper or copper alloys, although other metals may be suitable. For example, the conductive features disclosed herein, such as the conductive features 806a and 806b, can comprise fine-grain metal (e.g., a fine-grain copper).

Thus, in direct bonding processes, a first element 802 can be directly bonded to a second element 804 without an intervening adhesive. In some arrangements, the first element 802 can comprise a singulated element, such as a singulated integrated device die. In other arrangements, the first element 802 can comprise a carrier or substrate (e.g., a wafer) that includes a plurality (e.g., tens, hundreds, or more) of device regions that, when singulated, form a plurality of integrated device dies. Similarly, the second element 804 can comprise a singulated element, such as a singulated integrated device die. In other arrangements, the second element 804 can comprise a carrier or substrate (e.g., a wafer). The embodiments disclosed herein can accordingly apply to wafer-to-wafer (W2W), die-to-die (D2D), or die-to-wafer (D2W) bonding processes. In wafer-to-wafer (W2W) processes, two or more wafers can be directly bonded to one another (e.g., direct hybrid bonded) and singulated using a suitable singulation process. After singulation, side edges of the singulated structure (e.g., the side edges of the two bonded elements) may be substantially flush and may include markings indicative of the common singulation process for the bonded structure (e.g., saw markings if a saw singulation process is used).

As explained herein, the first and second elements 802 and 804 can be directly bonded to one another without an adhesive, which is different from a deposition process and results in a structurally different interface compared to a deposition. In one application, a width of the first element 802 in the bonded structure is similar to a width of the second element 804. In some other embodiments, a width of the first element 802 in the bonded structure 800 is different from a width of the second element 804. Similarly, the width or area of the larger element in the bonded structure may be at least 10% larger than the width or area of the smaller element. The first and second elements 802 and 804 can accordingly comprise non-deposited elements. Further, directly bonded structures 800, unlike deposited layers, can include a defect region along the bond interface 818 in which nanometer-scale voids (nanovoids) are present. The nanovoids may be formed due to activation of the bonding surfaces 812a and 812b (e.g., exposure to a plasma). As explained above, the bond interface 818 can include concentration of materials from the activation and/or last chemical treatment processes. For example, in embodiments that utilize a nitrogen plasma for activation, a nitrogen peak can be formed at the bond interface 818. The nitrogen peak can be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen peak can be formed at the bond interface 818. In some embodiments, the bond interface 818 can comprise silicon oxynitride, silicon oxycarbonitride, or silicon carbonitride. As explained herein, the direct bond can comprise a covalent bond, which is stronger than van Der Waals bonds. The bonding layers 808a and 808b can also comprise polished surfaces that are planarized to a high degree of smoothness.

In various embodiments, the metal-to-metal bonds between the conductive features 806a and 806b can be joined such that metal grains grow into each other across the bond interface 818. In some embodiments, the metal is or includes copper, which can have grains oriented along the 111 crystal plane for improved copper diffusion across the bond interface 818. In some embodiments, the conductive features 806a and 806b may include nanotwinned copper grain structure, which can aid in merging the conductive features during annealing. The bond interface 818 can extend substantially entirely to at least a portion of the bonded conductive features 806a and 806b, such that there is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b, for example, as described in U.S. Pat. No. 11,195,748, which is incorporated by reference herein in its entirety and for all purposes.

Beneficially, the use of the hybrid bonding techniques described herein can enable extremely fine pitch between adjacent conductive features 806a and 806b, and/or small pad sizes. For example, in various embodiments, the pitch p (i.e., the distance from edge-to-edge or center-to-center, as shown in FIG. 24) between adjacent conductive features 806a (or 806b) can be in a range of 0.5 microns to 50 microns, in a range of 0.75 microns to 25 microns, in a range of 1 micron to 25 microns, in a range of 1 micron to 10 microns, or in a range of 1 micron to 5 microns. Further, a major lateral dimension (e.g., a pad diameter) can be small as well, e.g., in a range of 0.25 microns to 30 microns, in a range of 0.25 microns to 5 microns, or in a range of 0.5 microns to 5 microns.

As described above, the non-conductive bonding layers 808a, 808b can be directly bonded to one another without an adhesive and, subsequently, the bonded structure 800 can be annealed. Upon annealing, the conductive features 806a and 806b can expand and contact one another to form a metal-to-metal direct bond. In some embodiments, the materials of the conductive features 806a and 806b can interdiffuse during the annealing process.

### Examples Embodiments

In one aspect of the present disclosure, an element comprises a substrate, an interconnect structure over the substrate, wherein the interconnect structure has at least one conductor at least partially embedded in a dielectric material and the dielectric material comprising a first dielectric layer and a second dielectric layer disposed on the first dielectric layer, a first dielectric barrier layer disposed on the at least one conductor and between the first dielectric layer and the second dielectric layer, and a second conductive barrier layer disposed on the first dielectric barrier layer.

In another aspect of the present disclosure, an element comprises an interconnect structure having an upper hybrid direct bonding surface, a contact pad extending at least partially through the interconnect structure, a dielectric barrier layer disposed on and covering entire sidewalls of the contact pad, and a low-k dielectric layer disposed about the contact pad and the dielectric barrier layer.

In another aspect of the present disclosure, a device comprises a substrate, an interconnect structure disposed on the substrate, wherein the interconnect structure includes an upper hybrid direct bonding surface. The interconnect structure comprises a first dielectric layer disposed on the substrate, a plurality of conductors at least partially embedded in the interconnect structure embedded therein, a dielectric barrier layer having a first portion disposed on and covering at least a portion of sidewalls of the plurality of the conductors, a second dielectric layer disposed about the first portion of the dielectric barrier layer, wherein a second portion of the dielectric barrier layer extends between the first dielectric layer and second dielectric layer, the second portion of the dielectric barrier layer is angled relative to the first portion of the dielectric barrier layer.

In yet another aspect of the present disclosure a method for fabricating a semiconductor element comprises fabricating a device having an interconnect layer, wherein the interconnect layer comprises a contact pad embedded in a first dielectric layer and the contact pad forms part of a combined conductive feature, etching at least partially through the first dielectric layer at a depth from an upper surface of the interconnect layer exposing sidewalls of the combined conductive feature, coating at least the exposed surfaces of the combined conductive feature and a top surface of the unetched first dielectric layer with a dielectric barrier layer, providing a second dielectric material filling over the unetched first dielectric layer and between the combined conductive features, and preparing the upper surface of the interconnect layer for direct hybrid bonding to another element.

In some embodiments, the at least one conductor is completely buried in the dielectric material, wherein each of the at least one conductor comprises a contact pad, the contact pad forming part of a hybrid bonding surface, and wherein each of the conductor further comprises a via portion connected to the contact pad.

In some embodiments, the second dielectric layer comprises a low-k dielectric materiel. In some embodiments, the second dielectric layer comprises a non-low-k dielectric materiel.

In some embodiments, the contact pad is connected to an underlying conductive feature with a first conductive barrier layer disposed between the contact pad and the underlying conductive feature. In some embodiments, the contact pad is connected to the underlying conductive feature by way of an intervening via portion. In some embodiments, a second conductive barrier layer is disposed between the contact pad and the intervening via portion.

In some embodiments, the low-k dielectric layer extends to a depth covering the second conductive barrier layer, and wherein the dielectric barrier layer is disposed on and covers entire sidewalls formed by the contact pad and edges of the second conductive barrier layer.

In some embodiments, the low-k dielectric layer extends to a depth covering a partial thickness of the underlying conductive feature, and wherein the dielectric barrier layer is disposed on and covers entire sidewalls formed by the contact pad, the intervening via portion and the partial thickness of the underlying conductive feature.

In some embodiments, the underlying conductive feature is embedded in a first dielectric layer, and the dielectric barrier layer extends between the low-k dielectric layer and the first dielectric layer.

In some embodiments, the dielectric barrier layer disposed on each sidewall has a corner, and an approximately right angle turn is formed in the dielectric barrier layer between each sidewall and an interface between the low-k dielectric layer and the first dielectric layer.

In some embodiments, the contact pad and the intervening via portion are formed uniformly. In some embodiments, the contact pad and the intervening via portion are formed by a dual damascene process. In some embodiments, the contact pad directly connects to the underlying conductive feature without an intervening via portion.

In some embodiments, the element further comprises an upper dielectric layer disposed on the low-k dielectric layer, the upper dielectric layer forming at least part of the upper bonding surface. In some embodiments, the upper dielectric layer comprises a non-low-k dielectric material.

In some embodiments, the contact pad comprises metal. In some embodiments, the element, the contact pad comprises copper.

In some embodiments, the low-k dielectric layer comprises a material having a dielectric constant lower than 3.5. In some embodiments, a dielectric constant of the low-k dielectric material is lower than 3.0. In some embodiments, the low-k dielectric layer comprises one or more of the following materials, porous silicon oxide, organosilicate glass (SiCOH), and amorphous carbon.

In one aspect of the present disclosure, a bonded structure comprises the element disclosed above and a second element comprising a third dielectric layer and a second contact pad at least partially embedded in the third dielectric layer, wherein the low-k dielectric layer is directly bonded to the third dielectric layer without an adhesive and the contact pad is directly bonded to the second contact pad without an adhesive. In some embodiments, the third dielectric layer of the bonded structure as recited above comprises a low-k dielectric material.

Unless the context clearly requires otherwise, throughout the description and the claims, the words “comprise.” “comprising.” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein.” “above,” “below.” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could.” “might.” “may.” “e.g.,” “for example.” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. An element comprising:
a substrate;
an interconnect structure over the substrate, the interconnect structure having at least one conductor at least partially embedded in a dielectric material, the dielectric material comprising a first dielectric layer and a second dielectric layer disposed on the first dielectric layer;
a first dielectric barrier layer disposed on the at least one conductor and between the first dielectric layer and the second dielectric layer; and
a second conductive barrier layer disposed on the first dielectric barrier layer.

2. The element of claim 1, wherein the at least one conductor is completely buried in the dielectric material.

3. The element of claim 2, wherein each of the at least one conductor comprises a contact pad, the contact pad forming part of a hybrid bonding surface.

4. The element of claim 3, wherein each of the conductor further comprises a via portion connected to the contact pad.

5. The element of claim 1, wherein the second dielectric layer comprises a low-k dielectric material.

6. (canceled)

7. An element comprising:
an interconnect structure having an upper hybrid bonding surface;
a contact pad extending at least partially through the interconnect structure;
a dielectric barrier layer disposed on and covering entire sidewalls of the contact pad; and
a low-k dielectric layer disposed about the contact pad and the dielectric barrier layer.

8. The element of claim 7, wherein the contact pad is connected to an underlying conductive feature with a first conductive barrier layer disposed between the contact pad and the underlying conductive feature.

9. The element of claim 8, wherein the contact pad is connected to the underlying conductive feature by way of an intervening via portion.

10. The element of claim 9, wherein a second conductive barrier layer is disposed between the contact pad and the intervening via portion.

11. The element of claim 10, wherein the low-k dielectric layer extends to a depth covering the second conductive barrier layer, and wherein the dielectric barrier layer is disposed on and covers entire sidewalls formed by the contact pad and edges of the second conductive barrier layer.

12. The element of claim 10, wherein the low-k dielectric layer extends to a depth covering a partial thickness of the underlying conductive feature, and wherein the dielectric barrier layer is disposed on and covers entire sidewalls formed by the contact pad, the intervening via portion and the partial thickness of the underlying conductive feature.

13. The element of claim 8, wherein the underlying conductive feature is embedded in a first dielectric layer, and wherein the dielectric barrier layer extends between the low-k dielectric layer and the first dielectric layer.

14. The element of claim 13, wherein the dielectric barrier layer disposed on each sidewall has a corner.

15. The element of claim 13, wherein an approximately right angle turn is formed in the dielectric barrier layer between each sidewall and an interface between the low-k dielectric layer and the first dielectric layer.

16. The element of claim 9, wherein the contact pad and the intervening via portion are formed uniformly.

17. (canceled)

18. The element of claim 8, wherein the contact pad directly connects to the underlying conductive feature without an intervening via portion.

19. The element of claim 7, further comprising an upper dielectric layer disposed on the low-k dielectric layer, the upper dielectric layer forming at least part of the upper hybrid bonding surface.

20. (canceled)

21. (canceled)

22. (canceled)

23. (canceled)

24. (canceled)

25. (canceled)

26. A bonded structure comprising the element of claim 7 and a second element comprising a third dielectric layer and a second contact pad at least partially embedded in the third dielectric layer, wherein the low-k dielectric layer is directly bonded to the third dielectric layer without an adhesive and the contact pad is directly bonded to the second contact pad without an adhesive.

27. (canceled)

28. A device comprising:
a substrate;
an interconnect structure disposed on the substrate, the interconnect structure having an upper hybrid bonding surface, the interconnect structure comprising:
a first dielectric layer disposed on the substrate;
a plurality of conductors at least partially embedded in the interconnect structure;
a dielectric barrier layer having a first portion disposed on and covering at least a portion of sidewalls of the plurality of the conductors;
a second dielectric layer disposed about the first portion of the dielectric barrier layer; and
wherein a second portion of the dielectric barrier layer extends between the first dielectric layer and second dielectric layer, the second portion of the dielectric barrier layer is angled relative to the first portion of the dielectric barrier layer.

29. The device of claim 28, wherein the interconnect structure further comprising a conductive barrier layer disposed on the entire dielectric barrier layer.

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. (canceled)

54. (canceled)

55. (canceled)

56. (canceled)

57. (canceled)

58. (canceled)

59. (canceled)

60. (canceled)

61. (canceled)

62. (canceled)

63. (canceled)
